(19) United States
(12) Patent Application Publication
(10) Pub. No.: US 2026/0136863 A1
(43) Pub. Date: May 14, 2026

(54) METHOD FOR PROCESSING A WAFER AND METHOD FOR DIVIDING A WAFER

(71) Applicant: DISCO CORPORATION, Tokyo (JP)

(72) Inventors: Junichi KUKI, Tokyo (JP); Masafumi SAITO, Tokyo (JP)

(21) Appl. No.: 19/382,989

(22) Filed: Nov. 7, 2025

(30) Foreign Application Priority Data
Nov. 14, 2024 (JP) 2024-198921

(51) Int. Cl. H01L 21/78; B23K 26/364; B23K 26/40; B23K 101/40; H01L 21/304; H01L 21/683

(52) U.S. Cl. CPC H10P 54/00; B23K 26/364; B23K 26/40; H10P 52/00; H10P 72/7402; B23K 2101/40; H10P 72/7416

(57) ABSTRACT

A method for processing a wafer, which includes an insulating film on a surface thereof and forms a plurality of devices and streets thereon, by emitting laser beams along the streets to form grooves extending along the streets, includes a protective film forming step including forming a protective film on the surface of the wafer; a narrow groove forming step including emitting a first laser beam split in a widthwise direction within a width of the street on the wafer held on a chuck table into a plurality of beams, to form a plurality of narrow grooves extending along the street; a wide bottomed groove forming step including emitting a second laser beam having a predetermined width to eliminate the plurality of narrow grooves and form a bottomed groove having a predetermined width; and a protective film removing step including removing the protective film.

### CROSS REFERENCE TO RELATED APPLICATION

This application is based upon and claims the benefit of priority from the prior Japanese Patent Application No. 2024-198921 filed on Nov. 14, 2024; the entire contents of which are incorporated herein by reference.

### FIELD

The present disclosure relates to a method for processing a wafer and a method for dividing a wafer.

### BACKGROUND

Japanese Patent Application Laid-Open Publication No. 2024-105980 discloses a method for dividing a wafer by emitting a laser beam onto a surface of the wafer, where a plurality of devices and streets are formed. According to this method, the laser beam having a wavelength absorbable by the wafer irradiates the wafer along the streets so as to perform ablation processing with the wafer, thereby removing the surface of the wafer.

On the surface of such wafer processed in the above-described method, a protective film may be formed. In such a case, for dividing the wafer by cutting along the street, as disclosed in the above-referenced publication, a laser beam is emitted to irradiate the wafer from a side of the protective film, thereby forming two grooves along the street and a wide groove between the two grooves. As such, by forming the wide groove, metal components such as TEGs and wires disposed on the street are removed by the ablation processing. In this regard, even when irradiation of the wafer with the laser beam generates debris such as molten material from metal components, the protective film may protect the devices formed on the surface of the wafer from the debris.

### SUMMARY

However, when forming a wide groove by laser beam irradiation, sizes of debris may increase in accordance with the width of the groove, resulting in a problem that the protective film may not sufficiently protect the devices. In this regard, while a protective film with increased thickness may protect the devices from debris, such protective film may increase an amount of resin material required for forming, and forming such protective films may require a longer time, thereby lowering productivity.

The present disclosure has been made in view of such circumstances, and one of objects thereof is to provide a method for processing a wafer and a method for dividing a wafer, by which adverse effects due to scattered debris during laser beam irradiation may be suppressed.

According to one aspect of the present disclosure, a method for processing a wafer, which includes an insulating film on a surface thereof and forms a plurality of devices and streets thereon, by emitting laser beams along the streets to form grooves extending along the streets, includes a protective film forming step including forming a protective film on the surface of the wafer; a narrow groove forming step including emitting a first laser beam, which is split in a widthwise direction within a width of the street on the wafer held on a chuck table into a plurality of beams, to form a plurality of narrow grooves extending along the street; a wide bottomed groove forming step including emitting a second laser beam having a predetermined width which is less than or equal to the width of the street to eliminate the plurality of narrow grooves and form a bottomed groove having a predetermined width; and a protective film removing step including removing the protective film.

According to another aspect of the present disclosure, a method for processing a wafer, which includes an insulating film on a surface thereof and forms a plurality of devices and streets thereon, by emitting laser beams along the streets to form grooves extending along the streets, includes: a protective film forming step including forming a protective film on the surface of the wafer; a wide bottomed groove forming step including forming a bottomed groove having a predetermined width by emitting a first laser beam, which is split in a widthwise direction within a width of the street on the wafer held on a chuck table into a plurality of beams, and a second laser beam having a predetermined width which is less than or equal to the width of the street overlappingly; and a protective film removing step including removing the protective film.

According to another aspect of the present disclosure, a method for dividing a wafer, which includes an insulating film on a surface thereof and forms a plurality of devices and streets thereon, after forming grooves along the streets by emitting laser beams onto the wafer, includes: a protective film forming step including forming a protective film on the surface of the wafer; a narrow groove forming step including emitting a first laser beam, which is split in a widthwise direction within a width of the street on the wafer held on a chuck table into a plurality of beams, to form a plurality of narrow grooves extending along the streets; a wide bottomed groove forming step including emitting a second laser beam having a predetermined width which is less than or equal to the width of the street to eliminate the plurality of narrow grooves and form bottomed grooves having a predetermined width; a protective film removing step including removing the protective film; and a dividing step including dividing the wafer along the bottomed grooves formed in the wafer.

According to another aspect of the present disclosure, a method for dividing a wafer, which includes an insulating film on a surface thereof and forms a plurality of devices and streets thereon, after forming grooves along the streets by emitting laser beams onto the wafer, includes: a protective film forming step including forming a protective film on the surface of the wafer; a wide bottomed groove forming step including forming bottomed grooves having a predetermined width by emitting a first laser beam, which is split in a widthwise direction within a width of the street on the wafer held on a chuck table into a plurality of beams, and a second laser beam having a predetermined width which is less than or equal to the width of the street overlappingly; a protective film removing step including removing the protective film; and a dividing step including dividing the wafer along the bottomed grooves formed in the wafer.

According to the present disclosure, the first laser beam which is split into a plurality of beams breaks, for example, metal components into smaller pieces, and the second laser beam having a relatively large width forms bottomed grooves. By breaking the metal components into smaller pieces, debris scattering onto the protective film may be reduced in size, and the devices may be protected by the protective film so as not to be damaged by the debris. Accordingly, a need to increase thickness of the protective film may be eliminated, and productivity may be improved by reducing an amount of resin material for the protective film and shortening a time to form the protective film, while suppressing adverse effects causable by debris scattering during laser beam irradiation.

### BRIEF DESCRIPTION OF THE DRAWINGS

FIG. 1A is a perspective exterior view of a wafer used in a wafer dividing method according to an embodiment. FIG. 1B is a partial cross-sectional view of the wafer.

FIG. 2 is an explanatory view of a protective film forming step.

FIG. 3 is a schematic perspective view of a laser processing apparatus.

FIGS. 4A and 4B are explanatory views of a narrow groove forming step.

FIGS. 5A and 5B are explanatory views of a wide bottomed groove forming step.

FIGS. 6A and 6B are schematic explanatory views of a flow of laser irradiation in the narrow groove forming step and the wide bottomed groove forming step according to the embodiment. FIG. 6C is a modified example of the embodiment. FIG. 6D is another modified example of the embodiment.

FIG. 7 is an explanatory view of a protective film removing step.

FIG. 8 is an explanatory view of an example of a dividing step.

FIGS. 9A and 9B are explanatory views of another example of the dividing step.

FIGS. 10A and 10B are explanatory views of another example of the dividing step.

### DESCRIPTION OF EMBODIMENTS

Hereinafter, with reference to the accompanying drawings, a method for dividing a wafer including a method for processing a wafer according to the embodiment will be described. In the method for dividing a wafer according to the embodiment, a protective film forming step, a narrow groove forming step, a wide bottomed groove forming step, a protective film removing step, and a dividing step are performed in this order. It is to be noted that steps shown in the drawings of the embodiment are merely an example, and embodiment of the present disclosure is not limited to the configuration described herein.

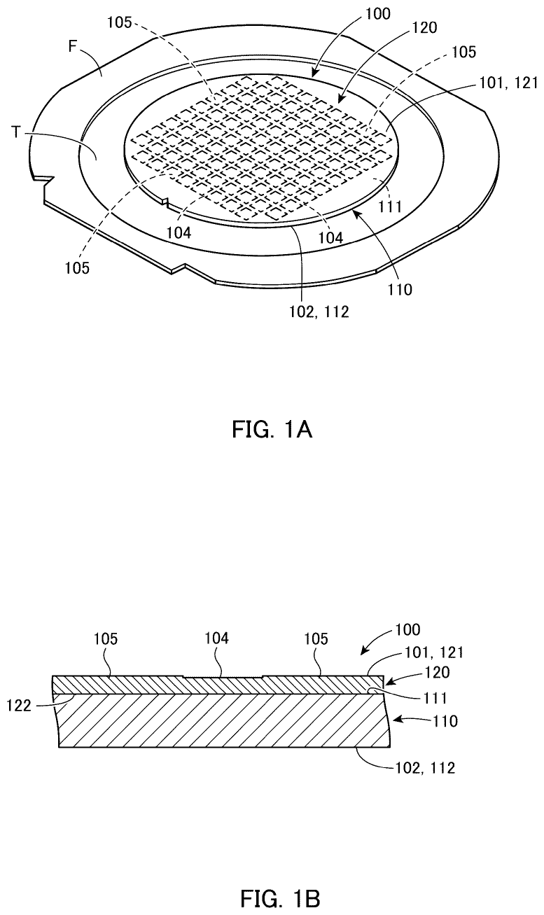

FIG. 1A is a perspective exterior view of a wafer used in the method for dividing a wafer according to the embodiment. FIG. 1B is a partial cross-sectional view of the wafer. As shown in FIG. 1A, a wafer 100 includes, for example, a disk-shaped substrate 110 having a front surface (first surface) 111 in a round form and a back surface (second surface) 112 in the round form on the opposite side to the front surface 111. The substrate 110 may be, typically, made of a semiconductor such as silicon (Si).

On the front surface 111 side of the substrate 110, a functional layer 120, formed of at least one film, is laminated. Specifically, the functional layer 120 is composed of metal components or a metal film serving as wires, an insulating film (including a low-k film) for insulating between the wires, a semiconductor film, and the like. The low-k film used for the functional layer 120 may be represented by, for example, an inorganic insulating film made of an inorganic material such as SiOF or SiOB, or an organic insulating film made of a polymer such as polyimide or parylene.

The back surface 112 of the above-described substrate 110 forms a back surface 102 of the wafer 100, and a front surface 121 of the functional layer 120 forms a front surface 101 of the wafer 100. On the front surface 111 of the substrate 110, the back surface 122 of the functional layer 120 is laminated. The front surface 101 side of the wafer 100 is partitioned into a plurality of regions by a plurality of linear streets 104 (dicing lines) having a predetermined width. In each of the small regions, a device 105 such as an IC (Integrated Circuit) including the functional layer 120 as a component is provided. As such, the wafer 100 forms the plurality of streets 104 and the plurality of devices 105. The functional layer 120 is also formed in the streets 104, and the metal components or the like are provided within the streets 104.

In the present embodiment, the substrate 110 of the wafer 100 is made of a semiconductor such as silicon, but the material, shape, structure, or size of the substrate 110 is not necessarily limited. For example, a wafer 100 including the substrate 110 made of another semiconductor, ceramics, resin, or metal may be used. Moreover, the type, number, shape, structure, size, or arrangement of the devices 105 is not necessarily limited.

Prior to the protective film forming step which will be described below, as shown in FIG. 1A, a tape T is attached to the back surface 102 of the wafer 100, and the wafer 100 is supported by an annular frame F via the tape T. As such, in the state where the wafer 100 is supported by the frame F, the front surface 101 of the wafer 100 is exposed upward. In the present embodiment, the wafer 100 is processed in each step in the state where the wafer 100 is supported through the tape T and the frame F; however, optionally, the wafer 100 may be processed without the tape T or the frame F. Further, the tape T may optionally be made of a different material or have a different function depending on processes or treatments in the steps.

### Protective Film Forming Step

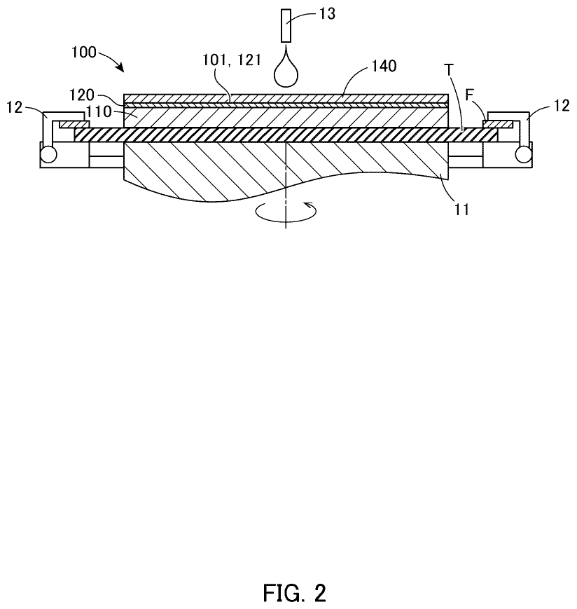

FIG. 2 is an explanatory view of the protective film forming step. As shown in FIG. 2, first, the protective film forming step is performed with a protective film forming apparatus (not shown). In the protective film forming step, the wafer 100 is held by suction on a holder table 11 via the tape T. Around the holder table 11, four clamps12 (two are not shown) are provided, and the frame F is clamped and fixed at four sides by the clamps 12. Above the holder table 11, a water-soluble resin nozzle 13 is provided, and a water-soluble resin is dripped onto the wafer 100 from a tip end of the water-soluble resin nozzle 13.

When a liquid pool is formed at a central area on the front surface of the wafer 100 by the dripped water-soluble resin, supply of the water-soluble resin is stopped, and the holder table 11 holding the wafer 100 is rotated. By centrifugal force caused by the rotation of the holder table 11, the entire front surface 101 of the wafer 100 is covered with the water-soluble resin. Thereafter, as the water-soluble resin solidifies, a protective film 140 is uniformly formed on a front surface 121 (upper surface) of the functional layer 120, which forms the front surface 101 of the wafer 100. The protective film 140 prevents debris from adhering to the devices 105 during laser processing, which will be described later. The water-soluble resin may be, for example, polyvinyl alcohol (PVA), polyethylene glycol (PEG), or the like.

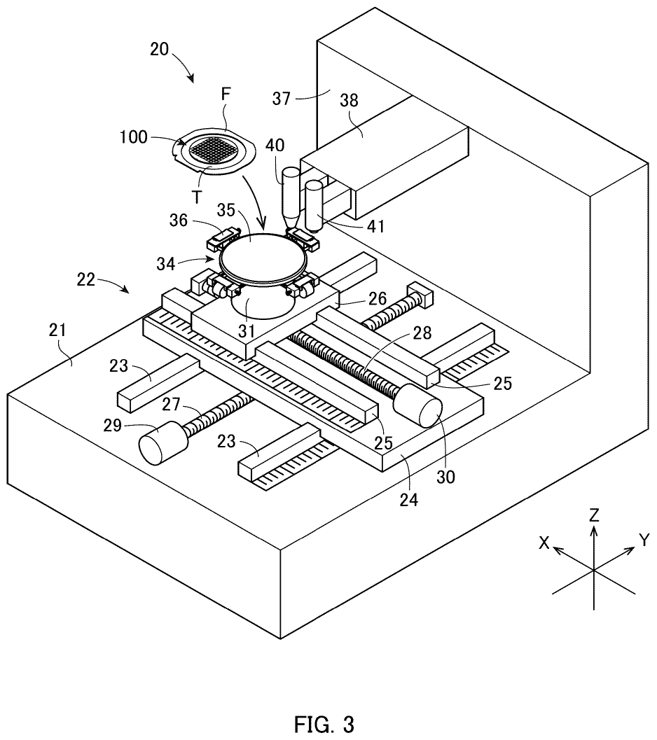

After the protective film forming step is performed, the narrow groove forming step and the wide bottomed groove forming step are performed sequentially in a laser processing apparatus 20. Before describing these steps, the laser processing apparatus 20 will be described with reference to FIG. 3. FIG. 3 is a schematic perspective view of the laser processing apparatus. It is to be noted that the laser processing apparatus may have any configuration capable of performing the laser processing steps of the present embodiment, and is not limited to the configuration shown in FIG. 3.

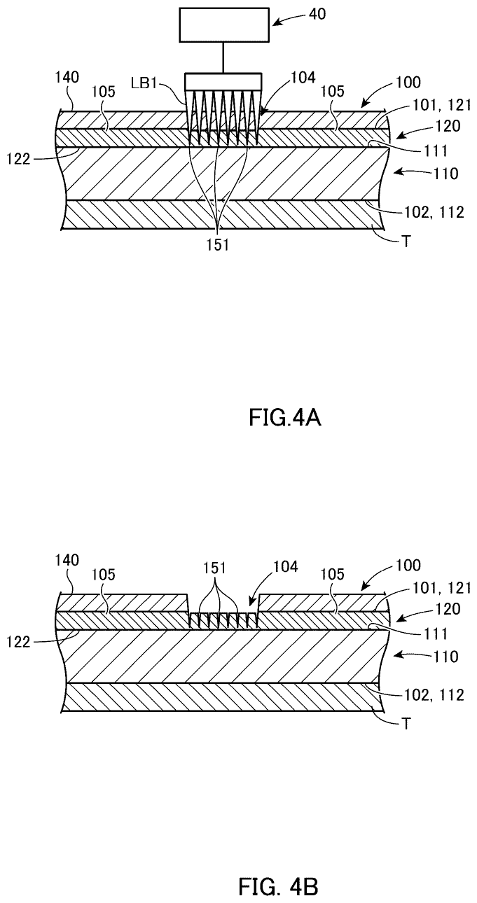

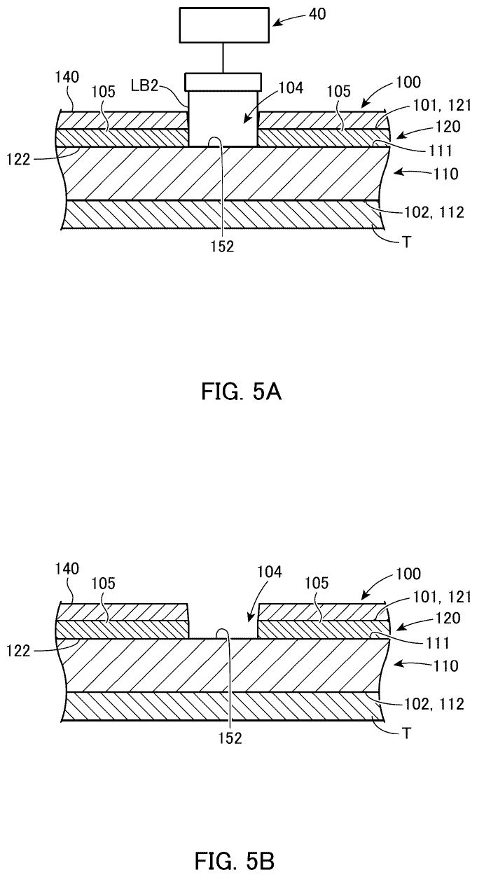

As shown in FIG. 3, the laser processing apparatus 20 is configured to process the wafer 100 with laser by relatively moving a laser emitter 40, which emits a first laser beam LB1 (see FIG. 4A) and a second laser beam LB2 (see FIG. 5A), and a chuck table 34, which holds the wafer 100 thereon.

On a base 21 of the laser processing apparatus 20, a moving mechanism 22 for moving the chuck table 34 in an X-axis direction and a Y-axis direction is provided. The moving mechanism 22 includes a pair of guide rails 23 disposed on the base 21 in parallel to the Y-axis direction, and a Y-axis table 24, which is drivable by a motor and slidably mounted on the pair of guide rails 23. The moving mechanism 22 further includes a pair of guide rails 25 disposed on an upper surface of the Y-axis table 24 in parallel to the X-axis direction, and an X-axis table 26, which is drivable by a motor and slidably mounted on the pair of guide rails 25.

On rear sides of the Y-axis table 24 and the X-axis table 26, threaded portions (not shown) are formed, and ball screws 27, 28 are screwed into the respective threaded portions. When driving motors 29, 30 connected to ends of the ball screws 27, 28, respectively, are rotationally driven, the chuck table 34 is moved along the guide rails 23, 25 in the X-axis direction and the Y-axis direction.

The moving mechanism 22 further includes a rotation mechanism 31 provided on the X-axis table 26. The rotation mechanism 31 supports the chuck table 34 from below, and the rotation mechanism 31 and the chuck table 34 are moved together along with the X-axis table 26 in the X-axis direction and the Y-axis direction. Further, the rotation mechanism 31 includes a driving motor and a pulley mechanism, which are not shown, and the chuck table 34 is rotated about a Z-axis.

Around the chuck table 34, four clamps 36 are provided, and the frame F is clamped and fixed at four sides by the clamps 36. On an upper surface of the chuck table 34, a holder surface 35 for holding the wafer 100 by suction is formed. The holder surface 35 is connected to a suction source (not shown), such as an ejector, through a flow path (not shown) provided inside the chuck table 34 and a valve (not shown).

On an upright wall 37 located rearward from the chuck table 34, a protruding arm portion 38 is provided, and at a tip end of the arm portion 38, the laser emitter 40 and an image-capturing camera 41 are provided so as to face the chuck table 34 in a vertical direction. The image-capturing camera 41 is provided sideward from the laser emitter 40 to capture an image of the front surface 101 of the wafer 100 held on the chuck table 34.

The laser emitter 40 emits the first laser beam LB1 and the second laser beam LB2 oscillated from a laser oscillator (not shown) toward the wafer 100 held on the chuck table 34. The laser oscillator includes, for example, a laser medium suitable for laser oscillation such as Nd: YAG, and generates pulsed laser beams LB1, LB2 having a wavelength absorbed by the wafer 100 (the functional layer 120) at a predetermined repetition frequency.

The laser emitter 40 includes an optical system such as a mirror and a lens for guiding the first laser beam LB1 and the second laser beam LB2 emitted in pulses from the laser oscillator to the wafer 100. The laser emitter 40 focuses the first laser beam LB1 and the second laser beam LB2 at a predetermined height position, for example, above the chuck table 34 (a position in a direction along the Z-axis). With the first laser beam LB1 and the second laser beam LB2 emitted from the laser emitter 40, the functional layer 120 in the wafer 100 is processed by ablation. In this context, process by ablation, or ablation processing refers to a phenomenon in which, when an emittance intensity of each of the laser beams LB1, LB2 exceeds a predetermined processing threshold, energies from the laser beams LB1, LB2 are converted into electronic, thermal, photochemical, and mechanical energies on a solid surface, whereby neutral atoms, molecules, positive and negative ions, radicals, clusters, electrons, and photons are explosively released, and the solid surface is etched.

### Narrow Groove Forming Step

Using this laser processing apparatus 20, the narrow groove forming step shown in FIGS. 4A and 4B is performed. FIGS. 4A and 4B are explanatory views of the narrow groove forming step. In particular, FIG. 4A is a cross-sectional view illustrating the first laser beam irradiating the wafer, and FIG. 4B is a cross-sectional view of the wafer after being processed with the first laser beam. In the narrow groove forming step, the first laser beam LB1 (laser beam), which is split in a widthwise direction within a width of a street 104 on the wafer 100 held on the chuck table 34 into a plurality of beams, is emitted, thereby forming a plurality of narrow grooves 151 (grooves) extending along the street 104. In other words, a plurality of narrow grooves 151 are formed in a street 104 in a single machining feed of laser emission. Optionally, the plurality of narrow grooves 151 may be formed by performing a plurality of machining feeds of laser emission (feeds in X-axis direction). In such a case, the first laser beam LB1 may not necessarily be split into a plurality of beams.

In the narrow groove forming step, first, the wafer 100 is conveyed onto the chuck table 34 via a conveyer, which is not shown. In this instance, the wafer 100 is placed on the chuck table 34 such that the protective film 140 formed on the wafer 100 faces upward. In this state, a negative pressure (suction force) generated by the suction source is applied to the upper surface of the chuck table 34, and the wafer 100 is held against the chuck table 34 via the tape T.

Next, an orientation of the chuck table 34 about the Z axis is adjusted by the rotation mechanism 31 so that an extending direction of the street 104 to be processed on the wafer 100 aligns parallel to the X axis. Further, a position of the chuck table 34 in the Y-axis direction is adjusted by the moving mechanism 22 such that the laser emitter 40 is positioned on an extension line along the extending direction of the street 104. Furthermore, an optical system of the laser emitter 40 is adjusted so as to focus the first laser beam LB1 at a height position suitable for processing of the wafer 100, and to split the first laser beam LB1 into the plurality of beams in the widthwise direction within the width of the street 104.

Thereafter, while the first laser beam LB1 split into the plurality of beams is emitted from the laser emitter 40, the moving mechanism 22 moves the chuck table 34 along the X axis at a predetermined speed (machining feed speed). Accordingly, the wafer 100 held on the chuck table 34 and a focal point of the first laser beam LB1 are relatively moved in the X-axis direction.

As a result, as shown in FIG. 4A, the first laser beam LB1 irradiates the street 104 from the protective film 140 side of the wafer 100, and portions of the functional layer 120 irradiated with the first laser beam LB1 is removed by ablation processing. Thus, as shown in FIG. 4B, the plurality of narrow grooves 151 extending along the street 104 are formed. By the plurality of narrow grooves 151, metal components and the like formed in the street 104 are divided and reduced in size.

At bottoms of the plurality of narrow grooves 151, the substrate 110 is likely to be exposed; however, the substrate 110 is not necessarily exposed at the bottoms of the plurality of narrow grooves 151. The plurality of narrow grooves 151 may reach the back surface 122 of the functional layer 120, or may not reach the back surface 122 of the functional layer 120.

Conditions for emitting the first laser beam LB1 are adjusted within a range, in which a plurality of narrow grooves 151 spaced apart from one another in the widthwise direction of the street 104 are properly formed. For example, the first laser beam LB1 is split into a state such that the branched beams are respectively focused on a plurality of points spaced apart from one another in the widthwise direction of the street 104 (that is, on a plurality of points spaced along the Y-axis). As such, by a single run of the chuck table 34 (scanning with the first laser beam LB1), the plurality of narrow grooves 151 are formed simultaneously. However, specific conditions for emitting the first laser beam LB1 and emitting modes thereof are not limited to these.

### Wide Bottomed Groove Forming Step

After the narrow groove forming step is completed, the wide bottomed groove forming step shown in FIGS. 5A and 5B is performed. FIGS. 5A and 5B are explanatory views of the wide bottomed groove forming step. In particular, FIG. 5A is a cross-sectional view illustrating a state in which the second laser beam irradiates the wafer, and FIG. 5B is a cross-sectional view of the wafer after laser processing with the second laser beam.

In the wide bottomed groove forming step, the second laser beam LB2 (laser beam) having a predetermined width equal or less than the width of the street 104 on the wafer 100 held on the chuck table 34 is emitted to eliminate the plurality of narrow grooves 151 shown in FIG. 4B, thereby forming a bottomed groove 152 (groove) having a predetermined width. When forming the bottomed groove 152 in the wide bottomed groove forming step, for example, the same or similar laser processing apparatus as the laser processing apparatus 20 described above may be used, and the processing procedure may be carried out in the same manner as the narrow groove forming step except that the laser beams LB1, LB2 to be emitted are different.

In the wide bottomed groove forming step, in the case where the above-described laser processing apparatus 20 is used, the optical system of the laser emitter 40 is adjusted to emit the second laser beam LB2 and branch or shape simultaneously into the predetermined width less than or equal to the width of the street 104. As such, the second laser beam LB2 irradiates the street 104 where the plurality of narrow grooves 151 are formed, in the same procedure as the narrow groove forming step. Thus, at the portions in the street 104, where the plurality of narrow grooves 151 are formed and where the functional layer 120 is irradiated with the second laser beam LB2, are removed by ablation processing. Accordingly, as shown in FIG. 5B, the plurality of narrow grooves 151 are unformed, and the bottomed groove 152 which is wide extending along the street 104 is formed. Since the metal components and the like formed in the street 104 have been reduced in size by the plurality of narrow grooves 151, debris generated from the metal components in forming the bottomed groove 152 is reduced in smaller size.

At a bottom of the wide bottomed groove 152, the substrate 110 is likely to be exposed; however, the substrate 110 is not necessarily exposed at the bottom of the wide bottomed groove 152. The wide bottomed groove 152 may reach the back surface 122 of the functional layer 120, or may not reach the back surface 122 of the functional layer 120.

Conditions for emitting the second laser beam LB2 are adjusted within a range, in which the bottomed groove 152 having the predetermined width in the widthwise direction of the street 104 is properly formed. As such, by a single run of the chuck table 34 (scanning with the second laser beam LB2), a single bottomed groove 152 having the predetermined width is formed. However, specific conditions for emitting the second laser beam LB2 and emitting modes thereof are not limited to these.

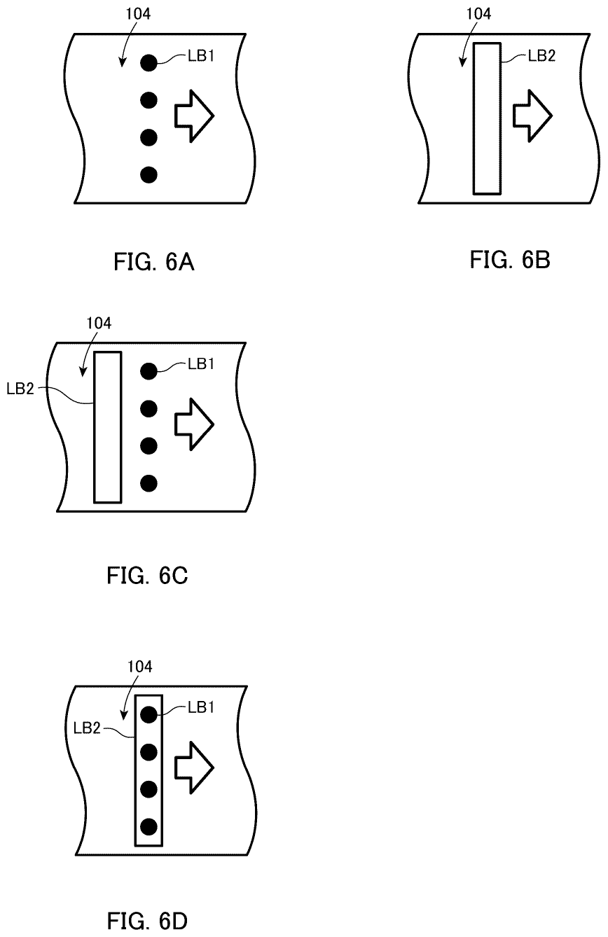

FIGS. 6A and 6B are schematic explanatory views of a flow of the laser emission in the narrow groove forming step and the wide bottomed groove forming step according to the embodiment. As shown in FIGS. 6A and 6B, in the present embodiment, the narrow groove forming step, in which the first laser beam LB1 is emitted onto the street 104, and the wide bottomed groove forming step, in which the second laser beam LB2 is emitted onto the street 104, are performed at different timing such that the narrow groove forming step precedes the wide bottomed groove forming step. Therefore, for example, in a given wafer 100, the narrow grooves 151 are formed in the narrow groove forming step in each of the streets 104 where the functional layer 120 is to be removed, and later the bottomed grooves 152 are formed in the wide bottomed groove forming step.

### Protective Film Removing Step

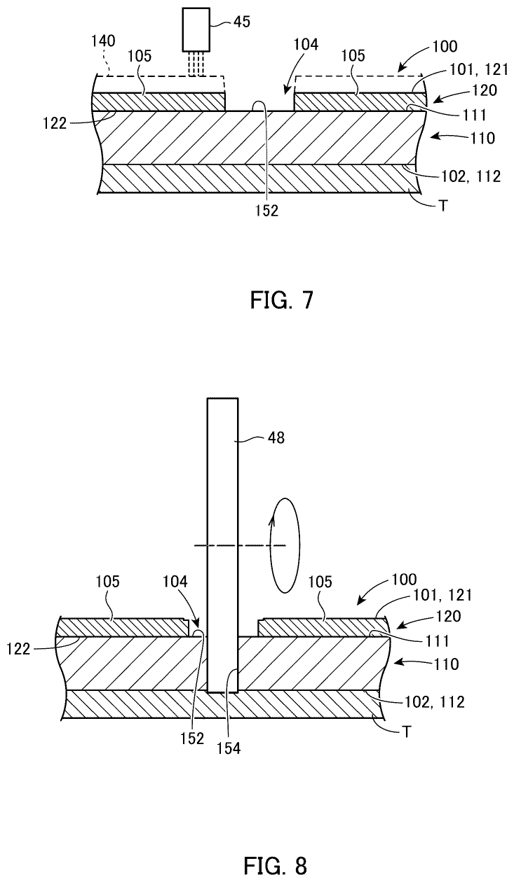

After the wide bottomed groove forming step is performed, as shown in FIG. 7, the protective film removing step for removing the protective film 140 formed on the wafer 100 is performed. FIG. 7 is an explanatory view of the protective film removing step. In the protective film removing step, cleaning water is supplied from a water supply nozzle 45 to the upper surface of the wafer 100, and the protective film 140 formed on the wafer 100 is removed. The protective film 140 made of water-soluble resin may be easily washed away with the cleaning water, and in this instance, debris generated in the previously performed narrow groove forming step and the wide bottomed groove forming step may also be washed away together with the protective film 140.

### Dividing Step

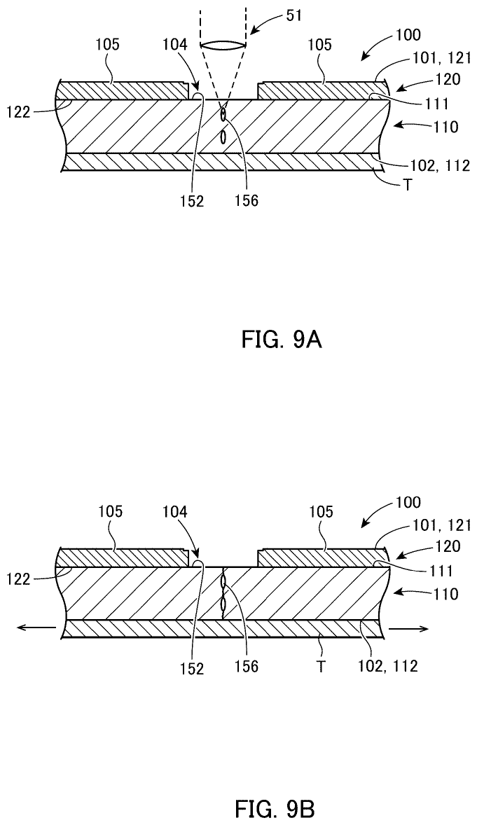

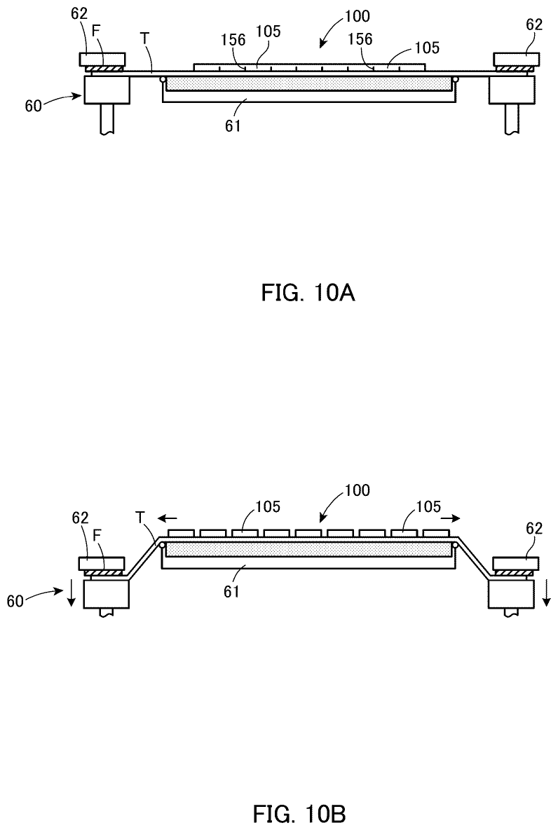

FIG. 8 is an explanatory view of an example of the dividing step. FIGS. 9A-9B and 10A-10B are explanatory views of another examples of the dividing step. After the protective film removing step is performed, as shown in FIGS. 8, 9A-9B, and 10A-10B, the dividing step in which the wafer 100 is divided along the bottomed grooves 152 formed in the wafer 100 is performed. The dividing step may employ various methods as long as the wafer 100 are divided along the bottomed grooves 152.

According to the dividing step shown in FIG. 8, the wafer 100 is held via the tape T on a chuck table (not shown) of a cutting apparatus, and thereafter, the wafer 100 is cut along the street 104 by a rotating cutting blade 48. As a result, as shown in FIG. 8, a cutting groove 154 is formed entirely through a thickness direction of the wafer 100 and to a depth reaching an upper surface of the tape T, whereby the wafer 100 is divided and device chips each including one device 105 are formed.

According to the dividing step shown in FIGS. 9A-9B, the wafer 100 is held via the tape T on a chuck table (not shown) of a laser processing apparatus designed for Stealth Dicing (registered trademark). Thereafter, as shown in FIG. 9A, a laser beam having a wavelength transmissive to the wafer 100 is emitted from a processing head 51 of the laser processing apparatus, and the laser beam is focused inside the wafer 100, thereby forming a processing mark.

By continuously forming such processing marks along the bottomed grooves 152 (street 104), a modified layer 156 serving as a starting point of dicing is formed in the wafer 100. In this context, the processing mark refers to a crack extended from a laser spot. Further, the modified layer 156 refers to a region in which density, refractive index, mechanical strength, and other physical properties inside the wafer 100 are differed from surroundings by irradiation with the laser beam, thereby lowering the strength locally relative to surroundings. As shown in FIG. 9B, after the modified layer 156 is formed in the wafer 100, the wafer 100 is diced into individual devices 105 along the modified layer 156 (the bottomed groove 152, the streets 104) by expanding the tape T.

Expansion of the tape T in the dividing step may be performed using an expanding apparatus 60 as shown in FIGS. 10A-10B. After the modified layer 156 is formed in the wafer 100, the wafer 100 is held via the tape T on a table 61 of the expanding apparatus 60. Around the table 61, a plurality of clamps 62 are provided, and the frame F is clamped and fixed by the clamps 62. Thereafter, the clamps 62 are lowered so that the table 61 and the clamps 62 are separated from each other. Accordingly, the tape T is expanded in a radial direction, and an external force acts on the modified layer 156 where the strength is reduced, whereby the wafer 100 is diced into individual devices 105 starting from the modified layer 156.

By performing the dividing step, the wafer 100 is diced along the bottomed groove 152, and device chips including the devices 105 are formed. The method of dividing the wafer 100 according to the present embodiment has been described above. As the wafer processing method, at least the steps other than the dividing step among the above-described steps are performed.

According to the above-described embodiment, by forming the narrow grooves 151 in the streets 104 in the narrow groove forming step, metal components on the streets 104 may be broken into smaller pieces. Therefore, even if debris including metal components is generated by removal of the functional layer 120 in the streets 104 in the wide bottomed groove forming step, the debris scattering onto the protective film 140 may be reduced in size. Thus, even if the protective film 140 is formed to be thinner or the amount of resin material for the protective film 140 is reduced, the devices 105 may be protected by the protective film 140 from being damaged by the debris. In other words, since a need to increase thickness of the protective film 140 is eliminated, the amount of resin material for the protective film 140 may be reduced while shortening a formation time of the protective film 140, thereby suppressing reduction in productivity, and adverse effects due to scattering of debris when the laser beams LB1, LB2 are emitted may be suppressed.

Note that embodiment of the present disclosure is not necessarily limited to the configuration described above but may be modified in various ways. In the embodiments described above, sizes or forms of the components illustrated in the accompanying drawings are not limited thereto but may be modified optionally within the scope of the effects of the present disclosure. Moreover, the embodiment may be modified optionally without departing from the scope of the object of the present disclosure.

For example, in the above-described embodiment, the wide bottomed groove forming step, in which the second laser beam LB2 is emitted, is performed after completion of the narrow groove forming step, in which the first laser beam LB1 is emitted; however, embodiment of the present disclosure is not limited thereto. In the above embodiment, without performing the narrow groove forming step, both the first laser beam LB1 and the second laser beam LB2 may be emitted in the wide bottomed groove forming step, and the first laser beam LB1 split into a plurality beams in the widthwise direction within the width of the street 104 and the second laser beam LB2 having the predetermined width less than or equal to the width of the street 104 may be emitted overlappingly to form the bottomed groove 152 having the predetermined width.

For example, as illustrated in the modified example shown in FIG. 6C, two laser emitters (not shown) may be arranged apart from each other by a predetermined distance along the extending direction of the street 104, and, immediately after the first laser beam LB1 is emitted, the second laser beam LB2 may be emitted such that the irradiations with the first laser beam LB1 and the second laser beam LB2 overlap. For another example, as illustrated in another modified example shown in FIG. 6D, positions to irradiate with the first laser beam LB1 and the second laser beam LB2 may overlap, and the first laser beam LB1 and the second laser beam LB2 may be alternately emitted in a short time.

As described above, the present disclosure has the effect that, by emission of the first laser beam LB1 split into a plurality of beams, metal components on the street are reduced in size, debris is reduced in size, and a need to form the protective film in increased thickness is eliminated, thereby improving productivity.

What is claimed is:

1. A method for processing a wafer, the wafer including an insulating film on a surface thereof and forming a plurality of devices and streets thereon, by emitting laser beams along the streets to form grooves extending along the streets, the method comprising:
a protective film forming step including forming a protective film on the surface of the wafer;
a narrow groove forming step including emitting a first laser beam, the first laser beam being split in a widthwise direction within a width of the street on the wafer held on a chuck table into a plurality of beams, to form a plurality of narrow grooves extending along the street;
a wide bottomed groove forming step including emitting a second laser beam having a predetermined width which is less than or equal to the width of the street to eliminate the plurality of narrow grooves and form a bottomed groove having a predetermined width; and
a protective film removing step including removing the protective film.

2. A method for processing a wafer, the wafer including an insulating film on a surface thereof and forming a plurality of devices and streets thereon, by emitting laser beams along the streets to form grooves extending along the streets, the method comprising:
a protective film forming step including forming a protective film on the surface of the wafer;
a wide bottomed groove forming step including forming a bottomed groove having a predetermined width by emitting a first laser beam, the first laser beam being split in a widthwise direction within a width of the street on the wafer held on a chuck table into a plurality of beams, and a second laser beam having a predetermined width which is less than or equal to the width of the street overlappingly; and
a protective film removing step including removing the protective film.

3. A method for dividing a wafer, the wafer including an insulating film on a surface thereof and forming a plurality of devices and streets thereon, after forming grooves along the streets by emitting laser beams onto the wafer, the method comprising:
a protective film forming step including forming a protective film on the surface of the wafer;
a narrow groove forming step including emitting a first laser beam, the first laser beam being split in a widthwise direction within a width of the street on the wafer held on a chuck table into a plurality of beams, to form a plurality of narrow grooves extending along the streets;
a wide bottomed groove forming step including emitting a second laser beam having a predetermined width which is less than or equal to the width of the street to eliminate the plurality of narrow grooves and form bottomed grooves having a predetermined width;
a protective film removing step including removing the protective film; and
a dividing step including dividing the wafer along the bottomed grooves formed in the wafer.

4. A method for dividing a wafer, the wafer including an insulating film on a surface thereof and forming a plurality of devices and streets thereon, after forming grooves along the streets by emitting laser beams onto the wafer, the method comprising:
a protective film forming step including forming a protective film on the surface of the wafer;
a wide bottomed groove forming step including forming bottomed grooves having a predetermined width by emitting a first laser beam, the first laser beam being split in a widthwise direction within a width of the street on the wafer held on a chuck table into a plurality of beams, and a second laser beam having a predetermined width which is less than or equal to the width of the street overlappingly;
a protective film removing step including removing the protective film; and
a dividing step including dividing the wafer along the bottomed grooves formed in the wafer.
